(19) United States
(12) Patent Application Publication
(10) Pub. No.: US 2009/0051003 A1
(43) Pub. Date: Feb. 26, 2009

(54) Methods and Structures Involving Electrically Programmable Fuses

(75) Inventors: Kangguo Cheng, Beacon, NY (US); Deok-kee Kim, Bedford Hills, NY (US); Chandrasekharan Kothandaraman, Hopewell Junction, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 11/843,946

(22) Filed: Aug. 23, 2007

(51) Int. Cl. H01L 29/00; H01L 21/44

(52) U.S. Cl. 257/529; 438/601; 257/E29.001; 257/E21.476

(57) ABSTRACT

A method for fabricating an eFuse, the method comprising disposing a crystalline silicon eFuse on a substrate having a fuse link portion, a first contact portion, and a second contact portion, wherein the fuse link is oriented parallel to the silicon crystal {110} plane direction, etching the eFuse using crystallographic orientation dependent wet etching in the {110} plane direction such that a corner at a junction of the fuse link an a contact portion is substantially square, operative to increase current density when an electric current flows through the fuse link, and forming a silicide layer atop the eFuse.

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to semiconductor fuses, and particularly to electrically programmable semiconductor fuses.

2. Description of Background

Electrically programmable fuses (eFuses) used in re-routing circuits often include poly-silicon strips with a thin layer of silicide covering the top of the strips. Passing current through the eFuse results in the electromigration of silicide material in the eFuse. Electromigration refers to the transport of material caused by the gradual movement of the ions in a conductor due to the momentum transfer between conducting electrons and diffusing metal atoms. The effect is more pronounced in applications where high direct current densities are used, such as in microelectronics and related structures.

With respect to eFuse devices, electromigration results in a higher resistance in the eFuse, effectively making the eFuse act as an open circuit. An exemplary structure to promote electromigration in an eFuse uses a specific geometry to promote crowding of the electrons that are flowing with the induced current. To facilitate the crowding of electrons, it is desirable to have an eFuse with a shape that has squared corners. When fabricating eFuses on a scale of, for example, 45 nm or less, the lithograph of the eFuse may cause the eFuse to have rounded corners. Thus, it is desirable to fabricate an eFuse with square corners that promote electron crowding, and in turn, electromigration in an eFuse.

### SUMMARY OF THE INVENTION

The shortcomings of the prior art are overcome and additional advantages are provided through the provision of a method for fabricating an eFuse, the method comprising disposing a crystalline silicon eFuse on a substrate having a fuse link portion, a first contact portion, and a second contact portion, wherein the fuse link is oriented parallel to the silicon crystal {110} plane direction, etching the eFuse using crystallographic orientation dependent wet etching in the {110} plane direction such that a corner at a junction of the fuse link an a contact portion is substantially square, operative to increase current density when an electric current flows through the fuse link, and forming a silicide layer atop the eFuse.

An alternate exemplary method for fabricating an eFuse, the method comprising, patterning a crystalline silicon layer of a semiconductor-on-insulator wafer using a lithograph such that regions of the crystalline silicon that will form an eFuse are defined, etching the crystalline silicon layer to form the eFuse, wherein a fuse link portion is substantially parallel to the {110} crystal plane direction, etching the eFuse using crystallographic orientation dependent wet etching in the {110} crystal plane direction such that a corner at a junction of the fuse link portion and a contact portion is sharpened, depositing a dielectric material over the surface of the eFuse and an insulating layer of the semiconductor-on insulator wafer, planarizing the surface of the eFuse, forming a silicide layer atop the eFuse, encapsulating the eFuse with an insulating material, patterning the insulating material to reveal contact points on the eFuse, and filling the exposed contact points with electrically conductive material.

An exemplary embodiment of a structure of an eFuse on a substrate comprising, a crystalline silicon first contact portion, a crystalline silicon second contact portion, a crystalline silicon fuse link portion, wherein the fuse link is oriented parallel to the silicon crystal {110} plane direction, a first corner at a junction of the fuse link and a contact portion, wherein the corner is substantially square such that current density increases when an electric current flows through the fuse link.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter which is regarded as the invention is particularly pointed out and distinctly claimed in the claims at the conclusion of the specification. The foregoing and other aspects, features, and advantages of the invention are apparent from the following detailed description taken in conjunction with the accompanying drawings in which:

FIG. 1 illustrates a top view of one example of an eFuse.

FIG. 2 illustrates a top view of an example of an eFuse.

FIGS. 3a-3g illustrate a side cross-section view of the methods used to fabricate an exemplary eFuse.

The detailed description explains the preferred embodiments of the invention, together with advantages and features, by way of example with reference to the drawings.

### DETAILED DESCRIPTION OF THE INVENTION

Systems and methods involving electrically programmable fuses are provided. Several exemplary embodiments are described.

In this regard, an electrically programmable fuse (eFuse) may be used to re-route circuits in semiconductors. For example, typical semiconductors include logic that is permanently etched on a chip. This logic cannot usually be changed once the chip is etched. However, eFuses may be used to dynamically reprogram semiconductor chips while they are in use.

The amount of electromigration in a material is determined by a number of factors such as, for example temperature, current density, and resistivity. Thus, one way to increase electromigration in an eFuse is to increase the current density in the eFuse. Since the geometry of an eFuse affects the current density, eFuses may be designed with geometries that promote electromigration.

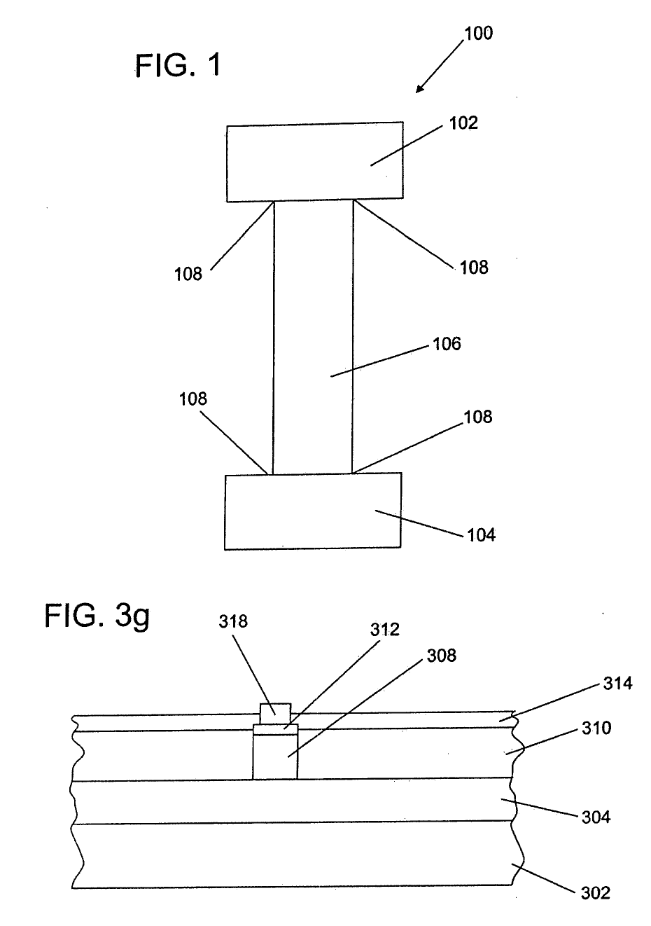

FIG. 1 illustrates and exemplary geometry that promotes a higher current density in an eFuse. EFuse 100 includes a first contact portion (anode portion) 102, a second contact portion (cathode portion) 104, and a link member portion 106. The corner portions 108 are at the points of contact between the link member portion 106 and the contact portions 102 and 104.

In operation, when a potential is induced across the link member portion 106, the substantially square corner portions 108 promote the crowding of electrons in the link member portion 106. The crowding of electrons increases the current density across the link member portion 106 and thus, increases electromigration in the eFuse 100.

When an eFuse is fabricated using an etching process such as reactive ion etching (RIE), a photoresist or mask is developed on a substrate such that when etched, an eFuse is formed. When a photoresist is used to fabricate small eFuses with, for example, a scale of 45 nm or less, the corners of the shapes in the photoresist tend to become rounded. The resultant photoresist developed on the substrate has rounded corners. When RIE is performed using the photoresist with rounded corners, an eFuse with rounded corners is produced.

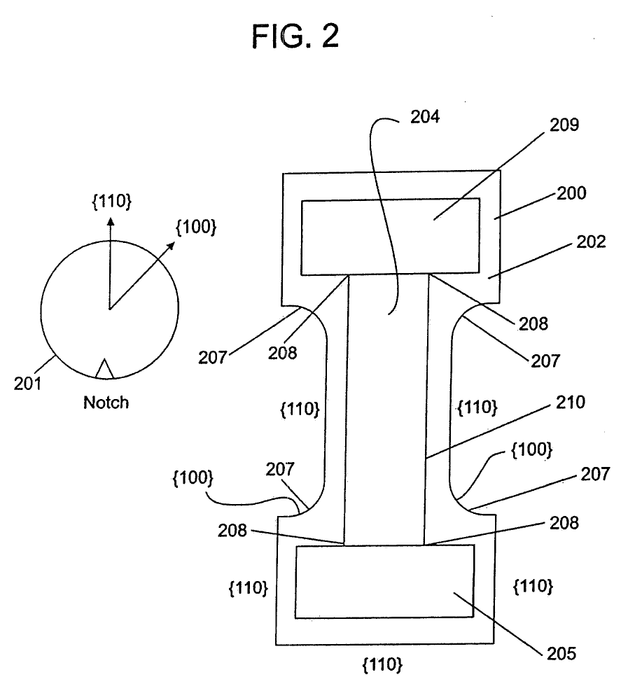

FIG. 2 illustrates the top profile of an eFuse 204 superimposed on an eFuse 200. In this illustrated embodiment, eFuse 200 has rounded corners 207. EFuse 204 illustrates the desired geometry of an eFuse with sharpened and substantially square corners 208. The illustrated embodiment is crystalline silicon. A first contact portion 205, a second contact portion 209, and a link portion 210 are orientated parallel with the {110} crystal plane, while the rounded corners 207 are orientated parallel with the {100} crystal plane. The plane directions and orientation is illustrated by the diagram 201.

One method of sharpening the corners of an eFuse such that they become substantially square is by using crystallographic orientation dependent silicon etching. Thus, in order to use crystallographic orientation dependent silicon etching, an eFuse fabricated from crystalline silicon may be used.

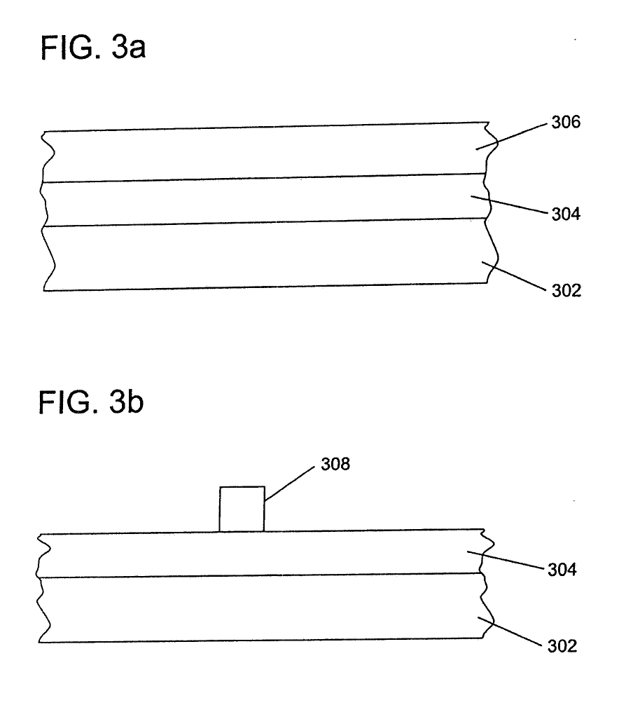

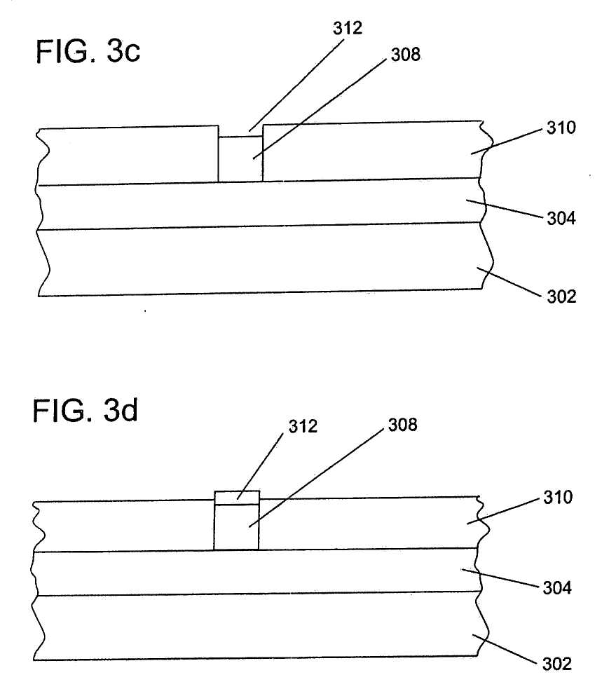

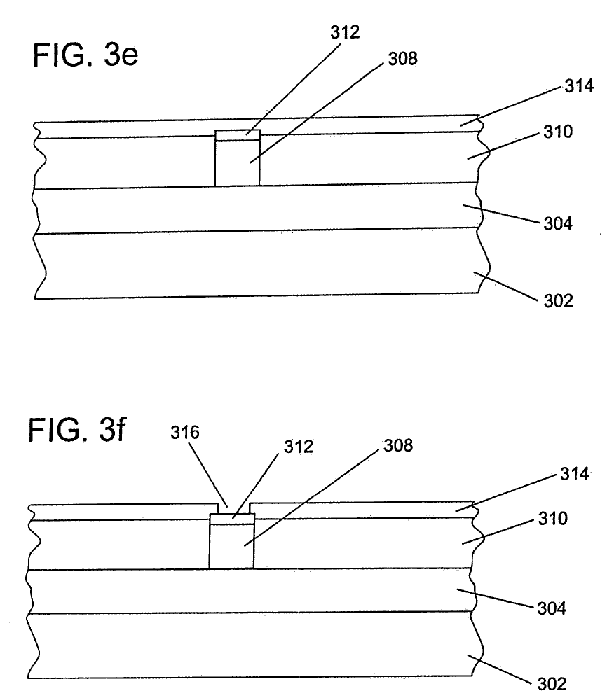

A method for fabricating an eFuse with substantially square corners is illustrated in FIGS. 3a-3g. In this regard, referring to FIG. 3a, semiconductor-on-insulator (SOI) wafer is formed. The SOI includes a semiconductor substrate 302, an insulating layer 304, and a crystalline semiconductor layer 306. The semiconductor substrate 302 and the crystalline semiconductor layer 306 may, for example, be crystalline silicon or any other suitable substrate material such as SiGe, GaAs and InP. The crystalline semiconductor layer 306 is electrically isolated from the substrate 302 by the insulating layer 304 that may comprise, for example silicon oxide and silicon nitride. The SOI wafer may be formed from any suitable technique such as, for example, wafer bonding or separation by implantation of oxygen (SIMOX).

FIG. 3b illustrates the eFuse 308 formed in the crystalline silicon layer 306. The eFuse 308 is formed by developing a photoresist on the crystalline silicon layer 306 to define the eFuse 308. The crystalline silicon layer 306 is then etched using a suitable process such as reactive ion etching (RIE).

The eFuse 308 resulting from the RIE process has rounded corners as shown in FIG. 2. Thus, it is desirable to make the corners substantially square. A crystallographic orientation dependent wet etching process in the {110} plane direction effectively squares the corners of the eFuse. Since the eFuse is oriented in the {110} direction, and the corners are orientated in the {100} direction, the crystallographic orientation dependent wet etching process in the {110} plane direction causes the rounded corners to be etched first. Thus, the corners of the eFuse are sharpened to be substantially square.

FIG. 3c illustrates a dielectric material 310 that is deposited over the entire surface of the eFuse 308 and the insulating layer 304. The dielectric material 310 may be, for example, silicon dioxide. Once the dielectric material 310 is deposited, gaps between crystalline silicon regions are filled by planarizing the dielectric material 310 using a suitable method such as chemical-mechanical polishing (CMP). The crystalline silicon may be implanted with a dopiant such as boron or arsenic.

Optionally, a silicide layer 312 may be formed atop the crystalline silicon of eFuse 308 as illustrated in FIG. 3d. It may be desirable to include the silicide layer 312 if the crystalline silicon is undoped to achieve the desired connectivity of the eFuse.

FIG. 3e illustrates an encapsulating layer 314 formed from an insulating material such as silicon nitride or silicon oxide. As illustrated in FIG. 3f, the encapsulating layer 314 is patterned and etched such that contacts holes 316 expose the contact portions of the eFuse 308. FIG. 3g illustrates contact holes 316 filled with an electric conducting material 318 such as, for example, tungsten.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. A method for fabricating an eFuse, the method comprising:
disposing a crystalline silicon eFuse on a substrate having a fuse link portion, a first contact portion, and a second contact portion, wherein the fuse link is oriented parallel to the silicon crystal {110} plane direction;
etching the eFuse using crystallographic orientation dependent wet etching in the {110} plane direction such that a corner at a junction of the fuse link an a contact portion is substantially square, operative to increase current density when an electric current flows through the fuse link; and
forming a silicide layer atop the eFuse.

2. A method for fabricating an eFuse, the method comprising:
patterning a crystalline silicon layer of a semiconductor-on-insulator wafer using a lithograph such that regions of the crystalline silicon that will form an eFuse are defined;
etching the crystalline silicon layer to form the eFuse, wherein a fuse link portion is substantially parallel to the {110} crystal plane direction;
etching the eFuse using crystallographic orientation dependent wet etching in the {110} crystal plane direction such that a corner at a junction of the fuse link portion and a contact portion is sharpened;
depositing a dielectric material over the surface of the eFuse and an insulating layer of the semiconductor-on insulator wafer;
planarizing the surface of the eFuse;
forming a silicide layer atop the eFuse;
encapsulating the eFuse with an insulating material;
patterning the insulating material to reveal contact points on the eFuse; and
filling the exposed contact points with electrically conductive material.

3. The method for fabricating an eFuse of claim 2, wherein the method further comprises doping the crystalline silicon layer.

4. The method for fabricating an eFuse of claim 2, wherein the silicon-on-insulator wafer is formed by:
forming an oxide layer on a first silicon wafer, wherein the first silicon wafer is crystalline silicon;
forming an oxide layer on a second silicon wafer; and
bonding the oxide layer of the first silicon wafer to the oxide layer of the second silicon wafer.

5. The method for fabricating an eFuse of claim 2, wherein the silicon-on-insulator wafer is formed by:
implanting oxygen ions in a crystalline silicon wafer to a depth of approximately 100 nm to 500 nm; and
annealing the crystalline silicon wafer such that a layer of silicon dioxide is formed under a crystalline silicon layer.

6. An eFuse on a substrate comprising:
a crystalline silicon first contact portion;
a crystalline silicon second contact portion;
a crystalline silicon fuse link portion, wherein the fuse link is oriented parallel to the silicon crystal {110} plane direction,
a first corner at a junction of the fuse link and a contact portion, wherein the corner is substantially square such that current density increases when an electric current flows through the fuse link.

7. The eFuse of claim 6, wherein a second corner at a junction of the fuse link and a contact portion, corner, is substantially square such that current density increases when an electric current flows through the fuse link.
